(19) United States
(12) Patent Application Publication
(10) Pub. No.: US 2024/0341103 A1
(43) Pub. Date: Oct. 10, 2024

(54) CIRCUIT ARRANGEMENT AND METHOD OF FORMING THE SAME

(71) Applicant: NANYANG TECHNOLOGICAL UNIVERSITY, Singapore (SG)

(72) Inventors: Somsubhra CHAKRABARTI, Singapore (SG); Putu Andhita DANANJAYA, Singapore (SG); Yong Chiang EE, Singapore (SG); Wen Siang LEW, Singapore (SG)

(21) Appl. No.: 18/700,067

(22) PCT Filed: Oct. 31, 2022
(86) PCT No.: PCT/SG2022/050788

§ 371 Date: Apr. 10, 2024

(30) Foreign Application Priority Data
Nov. 1, 2021 (SG) 10202112141V

(51) Int. Cl. H10B 63/00; H10N 70/00

(52) U.S. Cl. CPC H10B 63/30; H10N 70/063

(57) ABSTRACT

A circuit arrangement is provided. The circuit arrangement includes a plurality of two-terminal devices, a via interconnection circuit having a support structure, a plurality of through-vias defined through the support structure, and a plurality of via trenches defined in the support structure, the plurality of via trenches being arranged to allow electrical coupling to the plurality of through-vias, and a selection circuit having a plurality of selection devices, wherein, for each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias. According to a further embodiment, a method of forming the circuit arrangement is also provided.

### CROSS-REFERENCE TO RELATED APPLICATION

This application claims the benefit of priority of Singapore patent application No. 10202112141V, filed 1 Nov. 2021, the content of it being hereby incorporated by reference in its entirety for all purposes.

### TECHNICAL FIELD

Various embodiments relate to a circuit arrangement and a method of forming a circuit arrangement.

### BACKGROUND

In recent years, the demand for energy efficient memory technology with highly scalable feature has been on the rise. This is in line with the new age of computing with different computing approaches associated with various platforms to support emerging applications, such as big data, internet of things, and wearables. While known volatile and non-volatile memory technologies, e.g., SRAM (static random-access memory), DRAM (dynamic random access memory), and FLASH, have served well as the building blocks of different domains of memory technologies for decades, their scaling-reliability trade off and relatively high power consumption are foreseen as major challenges in future memory market. Resistive random-access memory (RRAM) is one of the most promising non-volatile memory technologies that has emerged in recent years. It is a two-terminal device having an insulator sandwiched in between two metal electrodes, i.e., a top electrode (TE) and a bottom electrode (BE), forming a metal-insulator-metal (MIM) structure. The insulator acts as the main switching layer, hosting different possible switching mechanisms triggered under an external electric field. RRAM is rapidly evolving to replace the existing memories in the near future with its long retention (10-year), high speed (10 ns), low power (0.1 pJ), and extremely small cell size (10 nm). Its two-terminal nature and highly scalable feature make RRAM an excellent candidate for high density systems, e.g., high density storage and highly connected brain inspired computing platform.

Most of the reported RRAM devices exhibit a bipolar switching behavior in which at least two distinct states, namely, a low resistance state (LRS) and a high resistance state (HRS), are achieved by applying external voltages with opposite polarities. These memory operations are known as set/write (HRS to LRS) and reset/erase (LRS to HRS). When the set voltage is applied across the RRAM device at HRS, a conducting filament is formed between the TE and the BE due to the generation and movement of defects within the switching layer, resulting in a decrease of the device resistance value. The subsequent reset process under the opposite voltage polarity causes the rupture in the filament leading to an increase of the device resistance. The set and reset processes observed in the RRAM devices can be engineered to have either abrupt or gradual nature depending on the requirements of the targeted field of applications.

In order to function properly in a large memory array, an RRAM device requires a selection device to work in tandem with it in order to mitigate the inherent sneak-path current issue in a crossbar array architecture. This selection device can be in the form of a complementary metal oxide semiconductor (CMOS) transistor or another two-terminal diode/selector type of devices. Different selection devices will lead to different RRAM integration schemes, e.g., one-transistor-one-RRAM (1T1R), one-transistor-n-RRAM (1TnR), and one-diode/selector-one-RRAM (1DIR or 1S1R), with specific device requirements to ensure the compatibility of the RRAM and the selection device. In 1T1R integration, the operating parameters of the RRAM structure are synchronised with the CMOS transistor characteristics to achieve a successful functional system. The values of LRS, HRS, and operating voltages should be able to meet the CMOS logic requirements for higher sensing accuracy and efficient read/write scheme. These device characteristics together with other parameters, e.g., endurance and retention, are highly dependent on the materials property as well as device dimension, e.g., area and height.

One of the promising properties of the RRAM device is that it can be scaled down to tens of nanometer and sometimes sub-nm, where the pitch of RRAM can also be scaled down to tens of nanometer. But the scale factors of the metallisation line and the via are not in proportion to the RRAM scale factor, which is an issue to integrate RRAM to CMOS logic. FIG. 1A shows a scenario where the pitch as well as the feature size of a certain metal line (e.g., three portions of the metal lines are represented by 150a) in CMOS back end of line (BEOL) is bigger than that of a RRAM 110a. The metal line 150a may be formed or defined in an inter layer dielectric (ILD) 152a. FIG. 1B shows a scenario where the via feature size is much bigger than the RRAM 110b feature size. There is an inter layer dielectric (ILD) 152b having a metal layer (e.g., M5) 150b (e.g., as a drain connector) and through-vias (e.g., V5) 154b defined therein and electrically coupled to one another. There is also another inter layer dielectric (ILD) 162b having a metal layer (e.g., M4) 160b and through-vias (e.g., V4) 164b defined therein and electrically coupled to one another. A protective layer 190b is provided on the ILD 152b and having trenches 192b that expose the metal layer 150b.

Additionally, a thin RRAM stack is difficult to incorporate into a deep trench process due to the high aspect ratio from lithography and etching process. In a known on-via vertical integration process, the RRAM stack is grown directly on top of the metal vias. Thus, the RRAM device dimensions, i.e., the stack height and area are limited by the via trench size. This imposes dimensional constraints in the development of the RRAM structures, which potentially results in a performance trade-off to facilitate the integration process. FIG. 2 shows, based on a known on-via approach, a situation where the via trenches (of height Vₕ) 292 defined in a protective layer 290 of nitrogen-doped silicon carbide (or Si—C—H—N compound) (e.g., NBLoK by Applied Materials, Inc.) is much higher than the height, Rₕ, of the RRAM stack 210. The known practice to overcome this issue is to fill-up the trenches 292 with tungsten or other materials plug. However, the characteristics of the RRAM stack 210 might change due to this via trench 292 fill-up process. As shown in FIG. 2, there is an inter layer dielectric (ILD) 252 having a metal layer (e.g., M5) 250 (e.g., as a drain connector) and through-vias (e.g., V5) 254 defined therein and electrically coupled to one another. There is also another inter layer dielectric (ILD) 262 having a metal layer (e.g., M4) 260 and through-vias (e.g., V4) 264 defined therein and electrically coupled to one another.

### SUMMARY

The invention is defined in the independent claims. Further embodiments of the invention are defined in the dependent claims.

According to an embodiment, a circuit arrangement is provided. The circuit arrangement includes a plurality of two-terminal devices, a via interconnection circuit having a support structure, a plurality of through-vias defined through the support structure, and a plurality of via trenches defined in the support structure, the plurality of via trenches being arranged to allow electrical coupling to the plurality of through-vias, and a selection circuit having a plurality of selection devices, wherein, for each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias.

According to an embodiment, a method of forming a circuit arrangement is provided. The method includes forming a plurality of two-terminal devices on a via interconnection circuit of the circuit arrangement, the via interconnection circuit having a support structure, a plurality of through-vias defined through the support structure, and a plurality of via trenches defined in the support structure, the plurality of via trenches being arranged to allow electrical coupling to the plurality of through-vias, and electrically coupling the plurality of two-terminal devices to a selection circuit of the circuit arrangement, the selection circuit having a plurality of selection devices, wherein, for each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show a schematic top view and a schematic cross-sectional view respectively illustrating comparison of the pitch and feature size mismatch of a resistive random-access memory (RRAM) and back end of line (BEOL) vias according to the prior art.

FIG. 2 shows a schematic cross-sectional view illustrating the mismatch of a resistive random-access memory (RRAM) stack height and a back end of line (BEOL) via trench height according to the prior art.

FIG. 3A shows a schematic cross-sectional view of a circuit arrangement, according to various embodiments.

FIG. 3B shows a flow chart illustrating a method of forming a circuit arrangement, according to various embodiments.

FIG. 4A shows a schematic cross-sectional view of an interconnect of an integrated circuit having a CMOS logic, while FIG. 4B shows a schematic top view of a top metal line drain pad array of the integrated circuit.

FIGS. 5 to 17B show, as cross-sectional and top views, various processing stages of a method for forming an integrated circuit, and corresponding results, according to various embodiments.

FIGS. 18A and 18B show schematic views of a circuit arrangement having a 1T1R configuration, according to various embodiments.

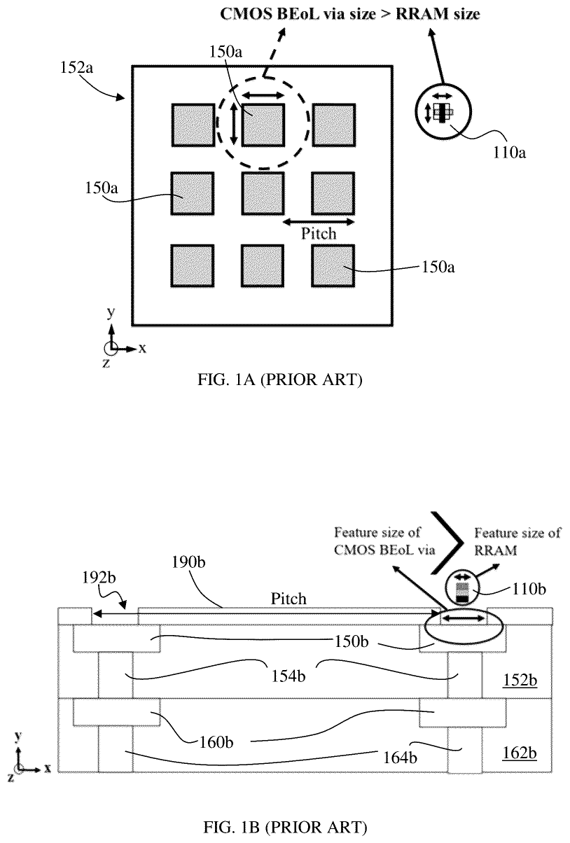

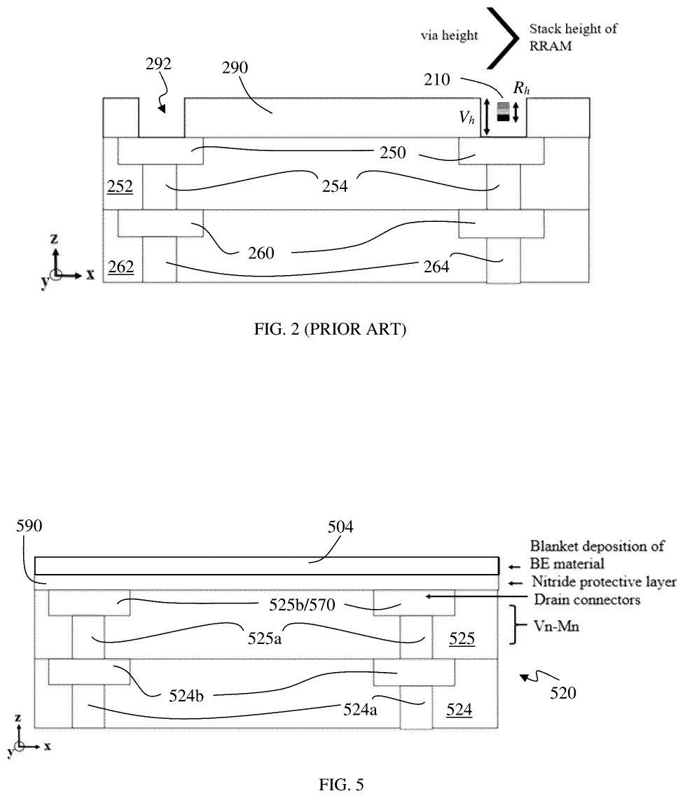

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” as applied to a numeric value encompasses the exact value and a reasonable variance.

As used herein, the term “and/or” includes any and all combinations of one or more of the associated listed items.

Various embodiments may relate to resistive random-access memory (RRAM) and method of off-via integration of RRAM for embedded system applications.

Generally, RRAMs can be implemented in both on-via (i.e., vertical) and off-via (i.e., planar structure) depending on the applications. The planar RRAM structure may be superior in some circumstances. Moreover, a crossbar structure is essentially off-via. In various embodiments, a method which integrates a two-terminal RRAM in its off-via structure to the CMOS (complementary metal-oxide-semiconductor) logic may be provided. The method may be applicable to any designs of two-terminal devices. In other words, the integration method of various embodiments is not limited to RRAMs, and any two-terminal devices may be integrated with CMOS logic using this method. Non-limiting examples of two-terminal devices include diodes, Zener diodes, laser diodes, Schottky diodes, light-emitting diodes (LEDs), photocells, phototransistors, and solar cells.

Exemplary embodiments may relate to the fabrication of off-via integration of RRAMs to a CMOS logic, for example, to achieve embedded memory array for storage class memory. It may allow one to (fully) utilise RRAM scalability potential and/or device performance optimisation without any restrictions from back end of line (BEOL) process limitation.

Methods and devices may be provided for fabricating a resistive random access memory array connected with a CMOS logic by using an off-via integration method. The method provides for the fabrication of RRAMs, each having two electrodes and one or more switching layers. The method may provide (full) utilisation of the scalability of RRAM independent of BEOL process. A protective layer may be used to protect the switching layer(s) from one or more subsequent processes. The device may be thermally stable after going through a thermal stress/budget of about 400° C. for about 3 hours. Transmission electron microscopy image and energy dispersive X-ray spectra, as will be described below, confirm minimal or no metal diffusion after annealing at about 400° C. for about 3 hours. The integration method of various embodiments may be applicable to one or more of any design rules, pitches, dimension, and technology nodes.

Compared to known approaches, the off-via planar RRAM integration method of various embodiments may enable the development of RRAM structures that are independent of the via trench dimension from the BEOL interconnect. It may be applicable to shallow via trench where the RRAM stack thickness is greater than the via trench height, and also to deep via trench where the via trench height is much larger than the RRAM stack height.

The switching layer as well as the interface between the switching layer and the electrodes of a RRAM device may determine the switching performance of the RRAM device. Hence, the switching layer and the interfaces may need to be protected from the fabrication of the RRAM stack and the subsequent processes. In various embodiments, a protective layer may be introduced to protect the switching layer and its interface during subsequent etching and/or integration processes, and to protect the chemical nature of the material (e.g., oxide material) of the switching layer. The protective layer generally may not or does not change the device characteristics.

In CMOS back end of line (BEL) fabrication, copper (Cu) interconnect annealing may be carried out to reduce the RC delay. The RRAMs should have enough thermal stability to overcome the annealing process. Various embodiments may provide an RRAM stack that have thermal stability to address or overcome the thermal budget for CMOS BEOL process.

Various embodiments may provide one or more resistive random access memory (RRAM) devices, which is a type of non-volatile memory, having a bottom electrode (BE), a switching layer, a protecting (or protection) layer to the switching layer, and a top electrode (TE). The switching layer may be arranged between the top and bottom electrodes. The protecting layer may be arranged between the switching layer and the top electrode. The switching layer may include a combination of two or three layers. The thickness of the protection layer may be about 3-5 nm.

The bottom electrode may include but not limited to tungsten (W), titanium nitride (TiN), titanium (Ti), and platinum (Pt). The switching layer may include but not limited to tantalum pentoxide (Ta₂O₅), hafnium oxide (HfO₂), titanium oxide (TiO₂), aluminium oxide (Al²O₃), and magnesium oxide (MgO). The top electrode may include but not limited to platinum (Pt), titanium (Ti), and tungsten (W). In various embodiments, the material of the protection layer may generally be the same material as that for the top electrode.

A thin metallic seed layer may be deposited before the bottom electrode for addition of a bottom electrode material which, e.g., may contain nitride. The seed layer may include but not limited to titanium (Ti), and tantalum (Ta).

In various embodiments, a stack having a BE of tungsten (W), a switching layer of Ta₂O₅, and a TE of platinum (Pt) may show minimal or no degradation of electrical characteristics after thermal stress at about 400° C. for about 3 hours.

The RRAM device is not formed in the via trench, but on a nitride layer over a metallisation line, e.g., Mₙ.

The RRAMs of various embodiments may be integrated with or electrically coupled to a CMOS logic or circuit.

The bottom electrode of the RRAM device may be formed on a nitride layer and the bottom electrode may be connected to a drain of a transistor of the CMOS logic by shallow via etching. The transistor drain of the CMOS front end of line (FEOL) may be extended to the upper metal layer through BEOL routing.

The top electrode of the RRAM device may be formed on a nitride layer and the top electrode may be connected to a bit line (BL) by shallow via etching.

The memory array described herein may have a minimum 32×32 memory cells.

It should be appreciated that the off-via integration method of various embodiments may not be limited to RRAM stacks, but may be applicable to any types of two-terminal devices.

The method of various embodiments may not be dependent on the vertical and horizontal dimension of the via trench. Thus, the method may enable flexibility in terms of device structural design to achieve the desired characteristic(s) for different applications.

The method of various embodiments may be applicable to any design rules, pitches dimension, and technology nodes.

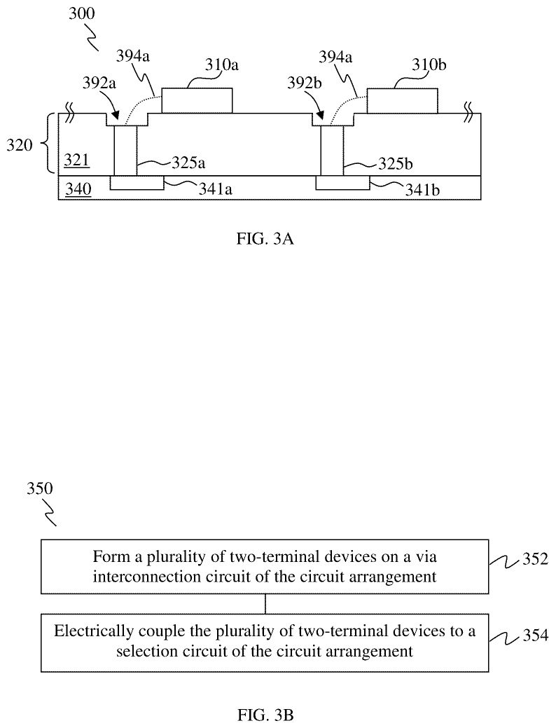

FIG. 3A shows a schematic cross-sectional view of a circuit arrangement 300, according to various embodiments. The circuit arrangement 300 includes a plurality of two-terminal devices 310a, 310b, a via interconnection circuit 320 having a support structure 321, a plurality of through-vias 325a, 325b defined through the support structure 321, and a plurality of via trenches 392a, 392b defined in the support structure 321, the plurality of via trenches 392a, 392b being arranged to allow electrical coupling to the plurality of through-vias 325a, 325b, and a selection circuit 340 having a plurality of selection devices 341a, 341b, wherein, for each two-terminal device 310a, 310b of the plurality of two-terminal devices 310a, 310b, the two-terminal device 310a, 310b is arranged outside of a respective via trench 392a, 392b of the plurality of via trenches 392a, 392b, the two-terminal device 310a, 310b being electrically coupled to a respective selection device 341a, 341b of the plurality of selection devices 341a, 341b in a one-to-one arrangement through the respective via trench 392a, 392b and a respective through-via 325a, 325b of the plurality of through-vias 325a, 325b.

In other words, a circuit arrangement 300 may be provided, having at least two two-terminal devices 310a, 310b, a via interconnection circuit 320, and a selection circuit (or a logic circuit or CMOS logic) 340 having at least two selection devices 341a, 341b. The via interconnection circuit 320 may include a support structure 321, at least two (conductive) through-vias 325a, 325b defined through the support structure 321, and at least two via trenches 392a, 392b defined in the support structure 321. The plurality of via trenches 392a, 392b may be arranged to allow electrical coupling (or electrical connection or electrical access) to the plurality of through-vias 325a, 325b. For each two-terminal device 310a, 310b, the two-terminal device 310a, 310b may be arranged outside of a respective via trench 392a, 392b. Each two-terminal device 310a, 310b may be electrically coupled (indicated by the curved dotted lines 394a, 394b) to a respective selection device 341a, 341b in a one-to-one (1-to-1) arrangement through the respective via trench 392a, 392b and a respective through-via 325a, 325b. In the one-to-one arrangement, one two-terminal device 310a, 310b is electrically coupled to one selection device 341a, 341b, where the selection device 341a, 341b is not shared with another two-terminal device. Each two-terminal device 310a, 310b may have a one-to-one relationship with a respective via trench 392a, 392b. Using the two-terminal device 310a as a non-limiting example, the two-terminal device 310a is electrically coupled 394a, in a one-to-one arrangement, to the respective selection device 341a through the respective via trench 392a and the respective through-via 325a.

The respective via trench 392a, 392b may correspond to or may be associated with the respective through-via 325a, 325b. The respective via trench 392a, 392b may be arranged coaxially or aligned with the respective through-via 325a, 325b.

Each two-terminal device 310a, 310b may have two electrodes. This may mean that each of the two terminals of the two-terminal device 310a, 310b may be or may include a respective electrode.

The via interconnection circuit 320 may enable connection or electrical coupling between the plurality of two-terminal devices 310a, 310b and the selection circuit 340. The via interconnection circuit 320 may be arranged between the plurality of two-terminal devices 310a, 310b and the selection circuit 340.

In various embodiments, as a respective two-terminal device 310a, 310b may be arranged outside of a respective via trench 392a, 392b that is associated with or corresponding to the respective two-terminal device 310a, 310b, such an arrangement is an off-via arrangement. In other words, each two-terminal device 310a, 310b may not be coaxially arranged or aligned with the corresponding respective via trench 392a, 392b (and also the corresponding respective through-via 325a, 325b). Such an off-via arrangement may help with the design, development, or fabrication of the two-terminal device 310a, 310b independent of the design or dimensions of the respective via trench 392a, 392b. In various embodiments, the two-terminal device 310a, 310b may be arranged entirely outside of the respective via trench 392a, 392b.

In the context of various embodiments, the plurality of two-terminal devices 310a, 310b may be integrated with the selection circuit 340. In this way, the circuit arrangement 300 may be an integrated circuit (arrangement) 300.

In the context of various embodiments, each of or a respective two-terminal device of the plurality of two-terminal devices 310a, 310b may be or may include, but not limited to, a diode, a Zener diode, a laser diode, a Schottky diode, a light-emitting diode (LED), a photocell, a phototransistor, or a solar cell. Nevertheless, it should be appreciated that any designs or types of two-terminal devices may be employed.

In the context of various embodiments, each of or a respective selection device of the plurality of selection devices 341a, 341b may be or may include a transistor or a diode.

While two two-terminal devices 310a, 310b, two through-vias 325a, 325b, two via trenches 392a, 392b, and two selection devices 341a, 341b are shown in FIG. 3A and correspondingly described, it should be appreciated there may be more than two, e.g., three, four, five, or any higher number, for each of them.

The via interconnection circuit 320 may further include at least one metal line electrically coupled to the plurality of through-vias 325a, 325b, wherein the plurality of via trenches 392a, 392b may be arranged to allow electrical coupling to the at least one metal line, and wherein each two-terminal device 310a, 310b may be electrically coupled to the respective selection device 341a, 341b (in the one-to-one arrangement) through the respective via trench 392a, 392b, the respective through-via 325a, 325b and the at least one metal line.

In various embodiments, the (or each) two-terminal device 310a, 310b may be or may include a memory device. For example, the memory device may be or may include a resistive random-access memory (RRAM).

The (or each) memory device may include a first electrode, a second electrode, and a resistive switching material (or layer) in between the first electrode and the second electrode. One of the first and second electrodes may be a top electrode (TE), and the other of the first and second electrodes may be a bottom electrode (BE). The resistive switching material may be or may include an insulating material. It should be appreciated that one or more or each memory device may include a plurality of resistive switching materials or layers.

The switching material (or layer) of the memory device may be arranged outside of the respective via trench 392a, 392b. The switching material (or layer) of the memory device may be arranged entirely outside of the respective via trench 392a, 392b.

The (or each) memory device may further include a protective layer (PL) in between the resistive switching material and one of the first and second electrodes. The protective layer may be arranged in between the resistive switching material and the top electrode (e.g., first electrode) of the memory device. The protective layer may help to protect the resistive switching material from damages and/or preserve the chemical nature of the resistive switching material, e.g., during subsequent (fabrication) processes. The protective layer may be electrically conductive.

Each selection device 341a, 341b of the plurality of selection devices 341a, 341b may be or may include a transistor. For example, the transistor may be or may include a PMOS (p-channel or p-type metal-oxide semiconductor) or an NMOS (n-channel or n-type metal-oxide semiconductor).

In embodiments having memory devices (e.g., RRAMs) as the two-terminal devices 310a, 310b, and transistors as the selection devices 341a, 341b, the circuit arrangement 100 has a one-to-one arrangement in the form of 1T1R, where “T” refers to transistor, and “R” refers to memory device or RRAM.

The support structure 321 may include a shielding layer (or protective layer), wherein the plurality of via trenches 392a, 392b may be defined through (or in) the shielding layer. The shielding layer may be or may include an insulating layer. The shielding layer may be or may include an oxide layer or a nitride layer.

FIG. 3B shows a flow chart 350 illustrating a method of forming a circuit arrangement (e.g., 300, FIG. 3A), according to various embodiments.

At 352, a plurality of two-terminal devices are formed on a via interconnection circuit of the circuit arrangement. The via interconnection circuit includes a support structure, a plurality of through-vias defined through the support structure, and a plurality of via trenches defined in the support structure, the plurality of via trenches being arranged to allow electrical coupling to the plurality of through-vias.

At 354, the plurality of two-terminal devices are electrically coupled to a selection circuit of the circuit arrangement. The selection circuit includes a plurality of selection devices.

For each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias.

The via interconnection circuit may further include at least one metal line electrically coupled to the plurality of through-vias, wherein the plurality of via trenches may be arranged to allow electrical coupling to the at least one metal line, wherein the two-terminal device may be electrically coupled to the respective selection device through the respective via trench, the respective through-via and the at least one metal line.

The two-terminal device may be or may include a memory device.

The (or each) memory device may include a first electrode, a second electrode, and a resistive switching material in between the first electrode and the second electrode.

The memory device may further include a protective layer in between the resistive switching material and one of the first and second electrodes.

Each selection device of the plurality of selection devices may include a transistor.

The support structure may include a shielding layer, wherein the plurality of via trenches may be defined through the shielding layer.

Various embodiments may provide a reliable way to integrate RRAMs, each having two terminals, namely a top electrode (TE) and a bottom electrode (BE), to CMOS logic. A layer having a switching material or materials is sandwiched in between the two electrodes. The integration scheme of various embodiments may be applicable to all types of pitch and design rules, including, for example, 1×, 1.4×, etc., which refer to the lateral dimension of VLSI (very large-scale integration) design. For example, 1.4×means 1.4 times densely packed and a 1.4 times reduction in chip area. Further, in the integration method disclosed herein, there may be no constraints imposed on the RRAM stack height and/or area from BEOL process specifications. In other words, the RRAM stack design may be (completely) independent from BEOL integration design. Thus, there may be a (complete) freedom in RRAM stack engineering to achieve preferable electrical output(s) that may be required to accomplish an embedded system. It is also not limited to any technology node.

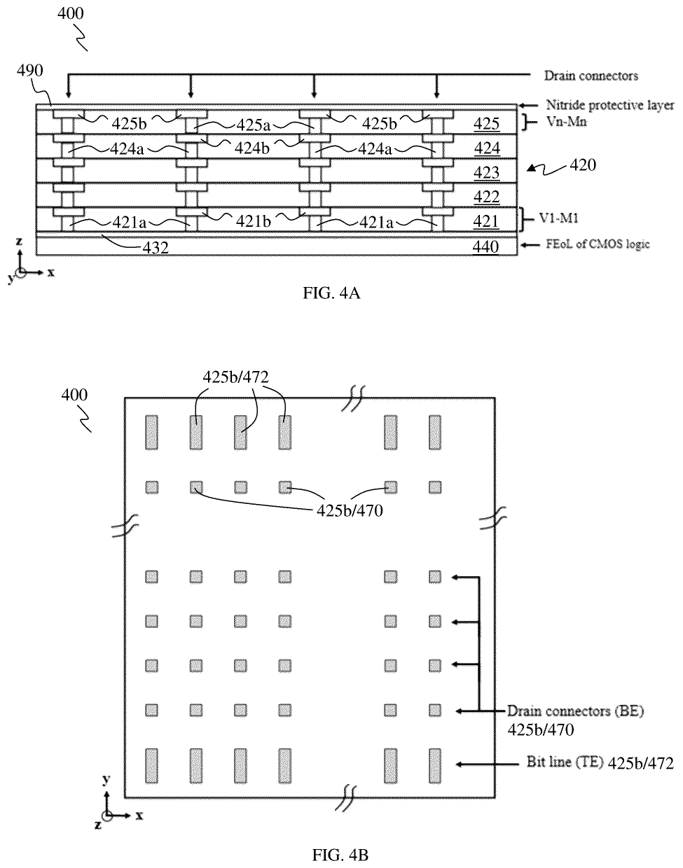

Various embodiments will now be further described by way of the following non-limiting examples with reference to FIGS. 4A to 18B.

Techniques disclosed herein may provide a process to integrate one or more RRAM structures to a selection circuit (e.g., in the form of a CMOS circuit or logic circuit), which may be applicable for high density data storage purpose, and/or neuromorphic applications for passive and/or semi passive crossbar structure.

FIG. 4A shows a schematic cross-sectional view of an interconnect of an integrated circuit (or circuit arrangement) 400 having a via interconnection circuit 420 and a selection circuit or CMOS logic 440, while FIG. 4B shows a schematic top view of a top metal line drain pad array of the integrated circuit 400.

The selection circuit (or logic circuit) 440 may be a CMOS front-end-of line (FEOL) circuit having a plurality of selection devices (not shown), e.g., transistors. A respective selection device may be electrically coupled to a respective two-terminal device (e.g., RRAM) (not shown) of the integrated circuit 400 in a one-to-one configuration via the via interconnection circuit 420. The selection circuit 440 may be employed for selection of two-terminal devices and also as a peripheral circuitry, which may be more reliable compared to known approaches that use a CMOS circuit only as peripheral circuitry and relies on the RRAM devices having non-linear characteristics. Due to this, the line resistance is increased and the RC delay decreases the speed of operation for the known approaches. Other known approaches use selecting devices that are provided outside of a CMOS logic, which results in an increase in the chip size.

The via interconnection circuit 420 of the integrated circuit 400 may include metallisation layers separated by inter-layer dielectrics (ILDs), which, e.g., may be low-k ILDs. As a non-limiting example as shown in FIG. 4A, there may be five ILDs, e.g., a first ILD 421, a second ILD 422, a third ILD 423, a fourth ILD 424, and a fifth ILD 425. A plurality of (electrically conductive) through-vias and a metallisation line (or layer), electrically coupled to each other, may be provided in the via interconnection circuit 420. A respective through-via and corresponding metallisation line may be represented using the notation Vₙ-Mₙ (n=1, 2, 3, etc.), where “V”=through-via, and M=metallisation line. For example, there may be a plurality of first through-vias (e.g., represented as V₁) 421a and a first metallisation line 421b (e.g., represented as M₁) in the first ILD (or bottom ILD) 421, which, as a whole, may be represented as V₁-M₁. The fourth ILD 424 with a plurality of fourth through-vias (e.g., V₄) 424a and a fourth metallisation line (e.g., M₄) 424b may be represented as a whole as V₄-M₄, while the fifth ILD (or top ILD) 425 with a plurality of fifth through-vias (e.g., V₅) 425a and a fifth metallisation line (e.g., M₅) 425b may be represented as V₅-M₅. Each ILD 421, 422, 423, 424, 425 may be arranged between respective two metal lines 421b, 424b, 425b. While four through-vias 421a, 424a, 425a are shown for each ILD 421, 422, 423, 424, 425, it should be appreciated that there may be a lower number or higher number of through-vias 421a, 424a, 425a for each ILD 421, 422, 423, 424, 425. Further, it should be appreciated that there may be a lower number or higher number of ILDs, with the corresponding through-vias and metallisation layers.

Using the first ILD 421 as a non-limiting example, the plurality of first through-vias 421a are electrically coupled to the first metallisation line (M₁) 421b. Similar arrangement may be provided for each of the remaining ILDs 422, 423, 424, 425. As shown in FIG. 4A, the plurality of through-vias 421a, 424a, 425a, and the metallisation lines 421b, 424b, 425b in the plurality of ILDs 421, 422, 423, 424, 425 are electrically coupled to each other. The plurality of through-vias 421a, 424a, 425a, and the metallisation lines 421b, 424b, 425b are also electrically coupled to the CMOS logic 440, including being electrically coupled to the plurality of selection devices (not shown) in the CMOS logic 440. Such selection devices may be or may include transistors. There is a conductive layer 432 that is part of the first metallisation line (M₁) 421b.

The fifth or top metallisation line 425b may include drain, bit line (BL) and word line (WL) connectors. The top view of the integrated circuit 400 shown in FIG. 4B illustrates the drain 470 and BL 472 connectors and their positions. The other connectors such as WL, source line etc. are not shown in FIG. 4B. Using RRAMs as a non-limiting example of a two-terminal device, the drain connectors 470 of the metallisation line 425b may be connected to or electrically coupled to the bottom electrodes (BE) of the RRAMs, and the bit line (BL) connectors 472 may be connected to or electrically coupled to the top electrodes (TE) of the RRAMs. Each RRAM is provided with a respective selection device in a one-to-one arrangement.

The top metallisation line 425b may be protected by an insulating (protective) layer (or shielding layer) 490 from oxidation and/or possible impurities (or contaminants) coming from subsequent processes. The shielding layer 490 may include silicon nitride or silicon oxide.

The described arrangement of the drain connectors 470 may be made in the BEOL of CMOS to fabricate 32×32, e.g., 1 kb 1T1R array configuration. Nevertheless, such an arrangement may be used in any other configurations, depending on the required designs.

The method for forming the integrated circuit of various embodiments will now be described with reference to FIGS. 5 to 17B using RRAMs as a non-limiting example.

The method starts with deposition of a metallic layer on an arrangement of ILDs having a nitride layer, where the metallic layer is used as the bottom electrode (BE) of an RRAM. One thin metallic seed layer may be deposited before the actual metallic layer for addition of the metallic layer with the nitride layer. The seed layer may include but not limited to titanium (Ti), and tantalum (Ta). The thickness of the seed layer may be about 1-2 nm. The BE material may include but not limited to tungsten (W), titanium nitride (TiN), tantalum nitride (TaN), titanium (Ti), tantalum (Ta) and platinum (Pt). The BE material may be deposited by thin film deposition technique, e.g., physical vapor deposition (PVD).

FIG. 5 shows a schematic cross-sectional view of a top portion of a part of the integrated circuit being fabricated, with a bottom electrode (BE) material 504 deposited thereon. There is a via interconnection circuit 520 having a plurality of ILDs, in the form of a top ILD 525, and another ILD 524 beneath the top ILD 525, and a protective layer (or shielding layer) 590 (e.g., a nitride protective layer) between the top ILD 525 and the BE material 504.

While not shown, there may be a seed layer deposited in between the nitride protecting layer 590 and the BE material 504. The seed layer may serve as an adhesive layer. In the top ILD 525, there are a plurality of through-vias 525a and a top metallisation layer 525b having drain connectors 570, while in the other ILD 524, there are also a plurality of through-vias 524a and a metallisation layer 524b. It should be appreciated that additional through-vias 524a, 525a may be provided in each ILD 524, 524 and/or additional ILDs may be provided. Further, it should be appreciated that the description in the context of the integrated circuit 400 may be applicable here. As a non-limiting example, the metallisation layer 525b may be the metallisation line 5 (M₅).

The process continues with the formation of a patterned mask. The mask may be made of a photoresist that may be deposited by spin coating. After baking the photoresist at about 90° C., the photoresist may be exposed by either optical lithography or e-beam lithography. The e-beam lithography may be used when the feature size is in the nm scale. An etching process may be done after lithography, e.g., either ICP-RIE (Inductively Coupled Plasma-Reactive Ion Etching) or ion-milling tool may be used. After etching, a solvent based remover may be used to clean/remove the remaining photoresist.

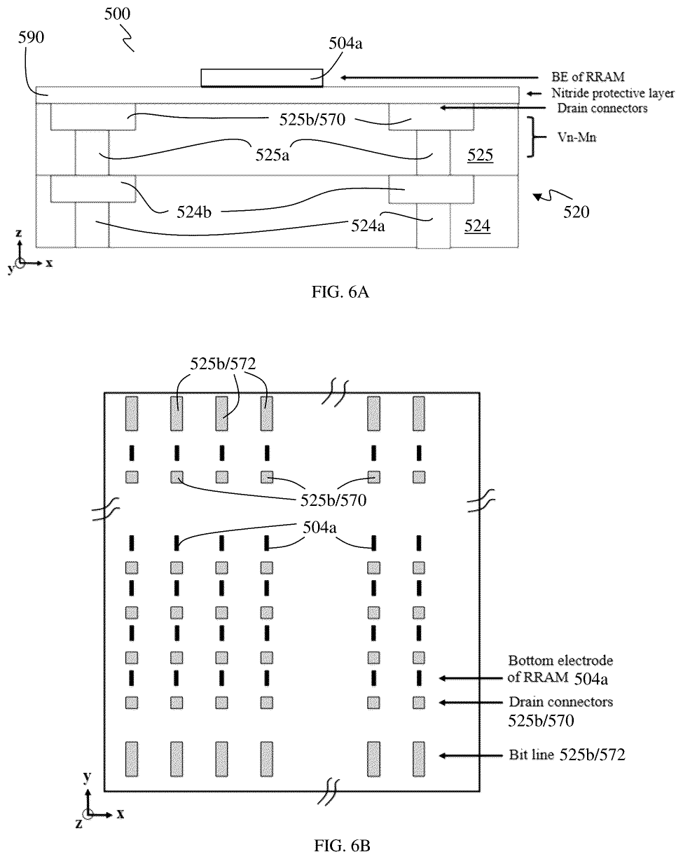

FIG. 6A shows a schematic cross-sectional view of the top portion of a part of the integrated circuit being fabricated, after the lithography and etching processes, and after removal of the photoresist. FIG. 6A illustrates the portion near the top metallisation layer interconnect where the BEs 504a of RRAMs are fabricated. As may be observed, the layer 504 of BE material (see FIG. 5) has been patterned and processed to form islands 504a to define the BEs for the RRAMs. The BE islands 504a are arranged away from or off-axis relative to the through-vias 524a, 525a. This may mean that the BE islands 504a are not arranged coaxially with the through-vias 524a, 525a, e.g., not arranged coaxially with the through-vias 524a, 525a in the longitudinal direction or longitudinal axis of the through-vias 524a, 525a. The thickness of the BEs 504a may range from a few nm to a few hundred nm. FIG. 6B shows the corresponding top view of the bottom electrode fabrication with respect to the drain pad array 570, and the bit line (BL) connectors 572 of the top metallisation layer 525b. The word line (WL) connectors of the top metallisation layer 525b are not shown in FIG. 6B. While not shown, it should be appreciated that WL may be (directly) connected or electrically coupled to transistors of the selection circuit or CMOS logic of the integrated circuit being fabricated.

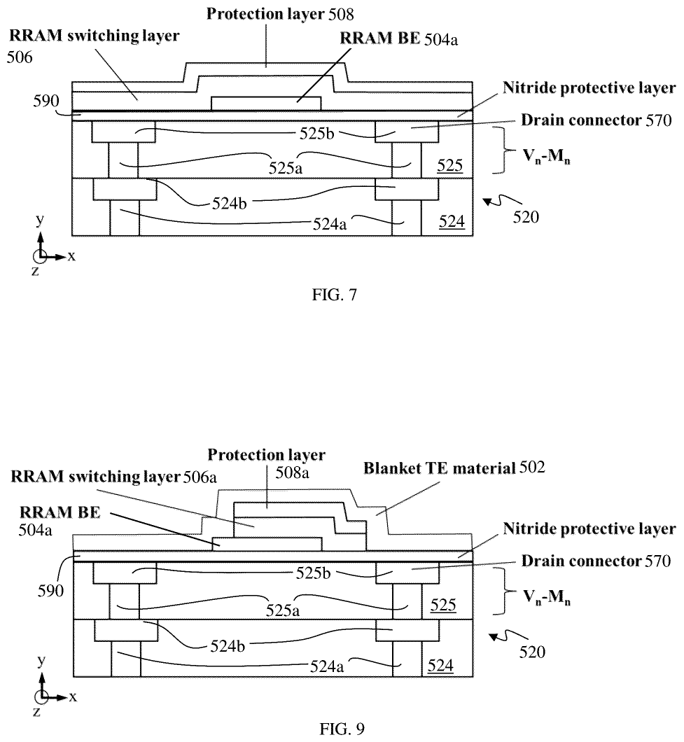

After fabrication of BEs 504a, a resistive switching material or layer may be deposited. A protective layer (PL) may then be deposited after the switching layer at the same time or in the same process, to protect the switching layer from subsequent etching processes, e.g., protection from physical damage from the subsequent processes. The PL may also preserve the chemical nature of the switching layer, e.g., the oxygen concentration (or atomic % of O₂ in the oxide) of the switching layer. FIG. 7 shows a schematic cross-sectional view of the top portion of a part of the integrated circuit being fabricated, after deposition of the switching layer 506 and the PL 508. The switching layer 506 may include an insulator. The switching layer 506 may include but not limited to tantalum pentoxide (Ta₂O₅), hafnium dioxide (HfO₂), aluminium oxide (Al₂O₃), titanium dioxide (TiO₂), magnesium oxide (MgO), tungsten trioxide (WO3), barium titanate (BaTiO₃) and strontium titanate (SrTiO₃). The switching layer 506 may include one or a combination of two or more of the materials described above. The thickness of the switching layer 506 may be between about 3 nm and about 50 nm (e.g., between about 3 nm and about 30 nm, between about 3 nm and about 10 nm, or between about 20 nm and about 50 nm) depending on the switching performance. The PL 508 may be or may include a conductive layer or material. The PL 508 may have the same material as that for the top electrode (TE) to be described below. It should be appreciated that the PL 508 is not an extension of the TE as the PL 508 is deposited just after the deposition of the switching layer 506 without breaking the vacuum in a sputter chamber. As will be described below, for the TE, one more step of litho-etch process is needed. The thickness of the PL 508 may be between about 3 nm and about 5 nm (e.g., between about 3 nm and about 4 nm, or between about 4 nm and about 5 nm).

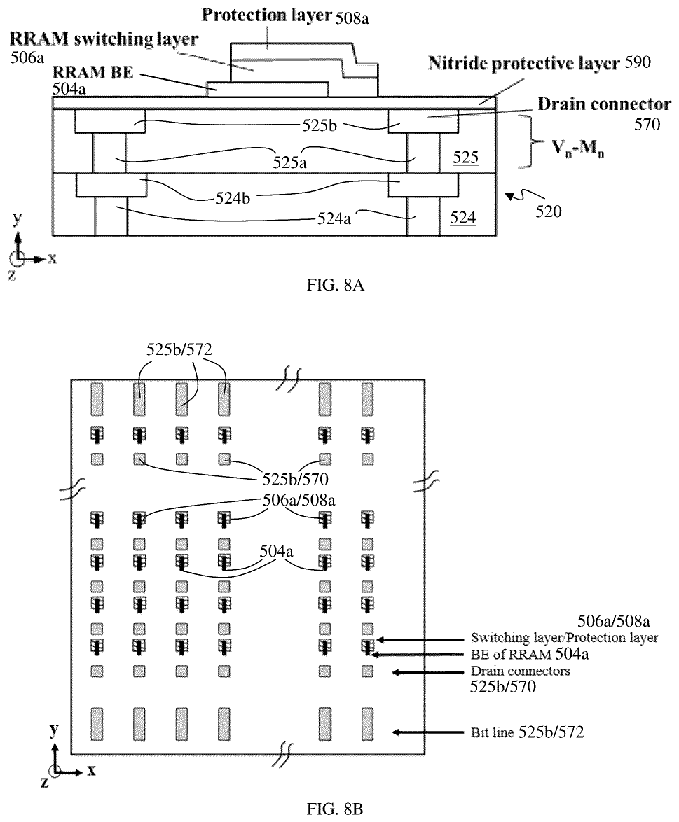

After deposition of the switching layer 506 and the PL 508, a lithography step followed by an etching step are performed to create a cross-point RRAM structure. A schematic cross-sectional view of the etched switching layer 506a and etched PL 508a on top of the BE 504a is shown in FIG. 8A, while the corresponding schematic top view is illustrated in FIG. 8B.

The next step in the fabrication process is top electrode (TE) deposition and patterning. FIG. 9 shows a schematic cross-sectional view of the top portion of a part of the integrated circuit being fabricated, after deposition of a conductive material 502 to be used as the top electrode (TE) of an RRAM. As shown in FIG. 9, the TE material 502 may be blanket deposited over the shielding or protective layer 590, the BE 504a, the switching layer 506a, and the PL 508a. The TE material 502 may be deposited by physical vapor deposition (PVD). The material for the TE 502 may include but not limited to titanium (Ti), platinum (Pt), tungsten (W), titanium nitride (TiN) and tantalum nitride (TaN). The thickness of the TE material 502 may be in the range of a few nm to a few hundred nm.

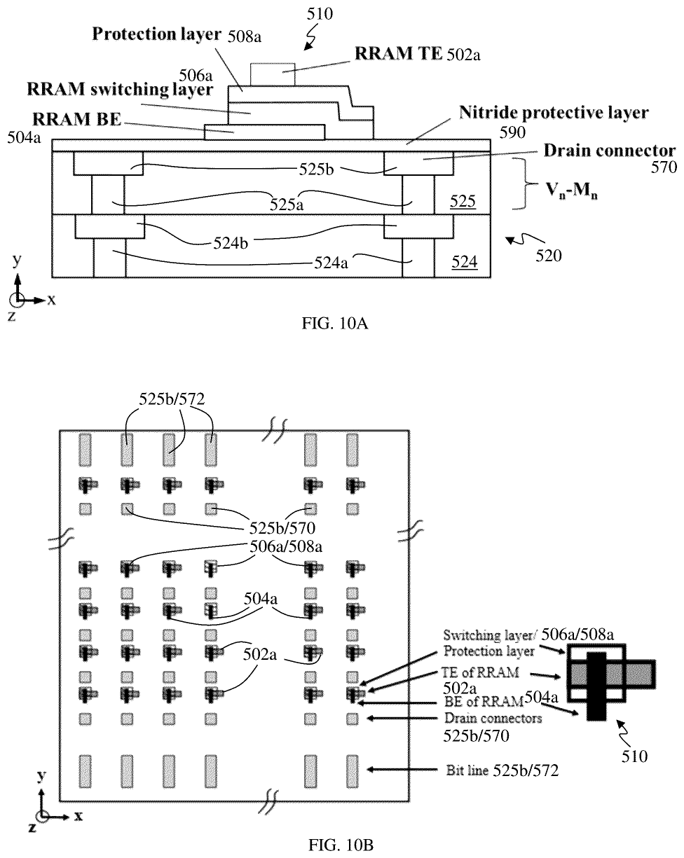

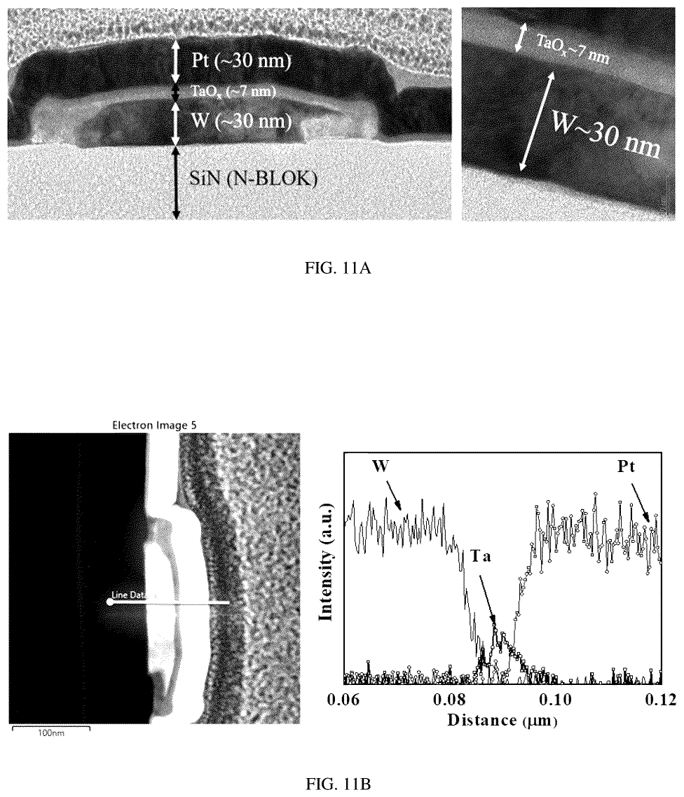

FIGS. 10A and 10B show respectively schematic cross-sectional and top views after patterning and etching of the TE material 502. The TE material 502 may be patterned using lithography and then etched to form islands 502a to define the TEs for the RRAMs. As may be observed in FIGS. 10A and 10B (including an enlarged view of the RRAMs 510), after lithography and etching, RRAMs 510 are formed, as part of the integrated circuit that is being fabricated. As seen in FIG. 10A, each RRAM 510 has a metal-insulator-metal (MIM) structure. The BE 504a and the TE 502a of each RRAM 510 may be arranged in a cross-bar configuration, perpendicularly to one another The RRAM stack 510 is arranged on the top layer of the CMOS back end of line (BEOL).

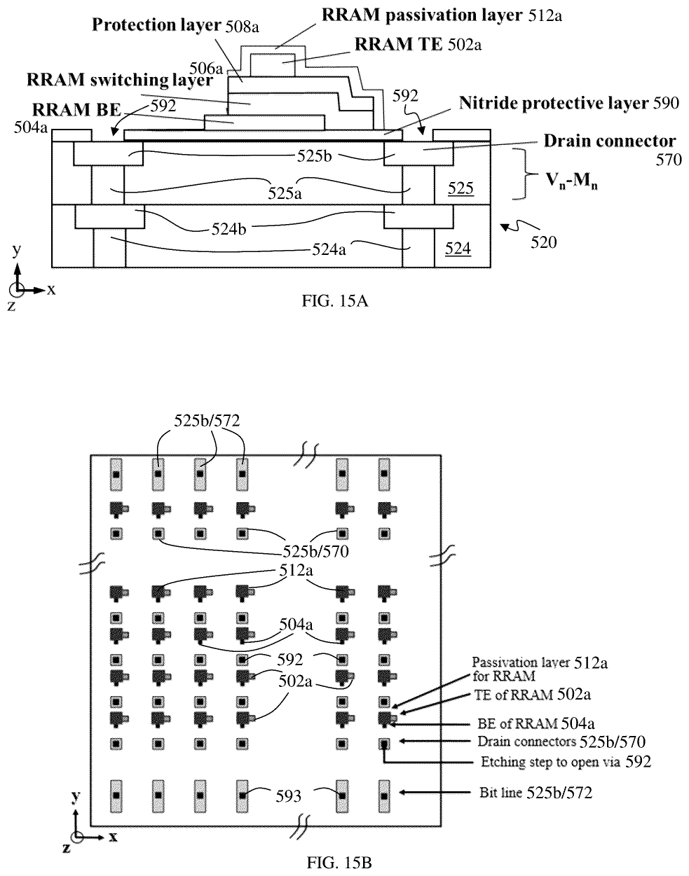

Further, as shown in FIGS. 10A and 10B, the RRAM stack 510 is not arranged coaxially with the through-vias 524a, 525a, and does not reside in the via trench (see further below in relation to FIG. 15A) in contrast to known approaches, but is arranged on a flat surface. The size of the RRAM 510 is not restricted by the size of the via trench. At the same time, the area or stack height of the RRAM 510 is also not limited by the via trench height. In some known approaches, the RRAM stack is formed in the via trench, where the RRAM stack height is less than the via trench height, with the remaining height/area of the trench being filled by tungsten (W) plug. However, for such a known approach, the characteristics of the RRAM may change. In contrast to the known approaches, for the integration method described herein, there is (complete) structural flexibility to design RRAM stacks to achieve desirable characteristics for different applications.

In various embodiments, there may be a need for the fabricated RRAM stacks (e.g., 510, FIGS. 10A and 10B) to comply with a certain thermal budget, e.g., the RRAM stack may need to go through thermal stress of 400° C. for 3 hours without degrading the characteristics. As described below, a RRAM stack is presented which addresses or overcomes the thermal budget without any or with minimal degradation in electrical characteristics.

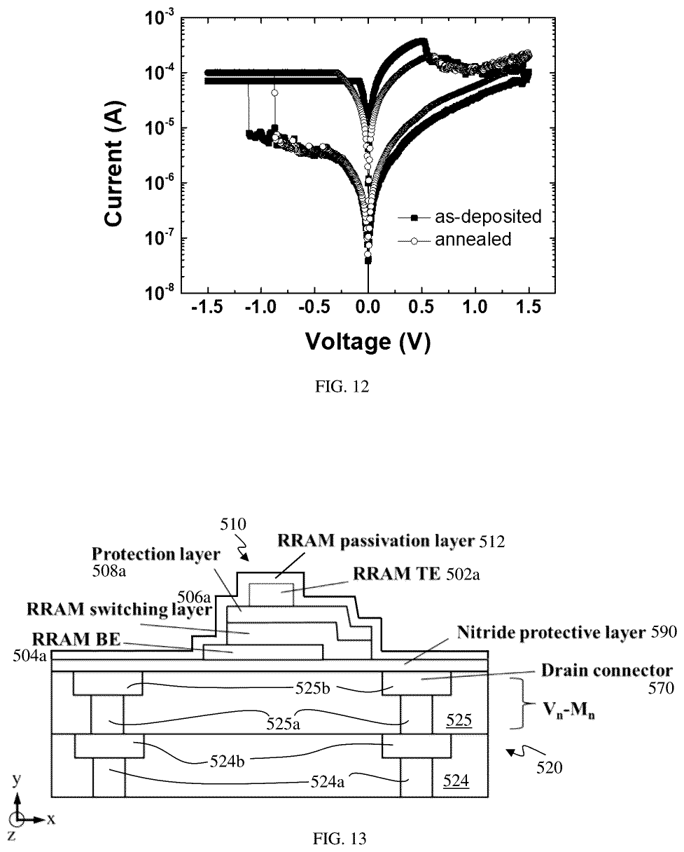

FIG. 11A shows a transmission electron microscope (TEM) image of a W/Ta₂O₅/Pt RRAM stack, in cross-section, after thermal stress at about 400° C. for about 3 hours. FIG. 11B shows the Energy Dispersive X-Ray (EDX) analysis of the W/Ta₂O₅/Pt RRAM stack, after the thermal stress, at the EDX line profile across the W/Ta₂O₅/Pt RRAM stack as indicated in FIG. 11B. There is no sign of metal diffusion after the thermal stress test. FIG. 12 shows the current-voltage (I-V) characteristics of the W/Ta₂O₅/Pt RRAM stack before (see results for “as-deposited”) and after (see results for “annealed”) the thermal stress. There is no sign of device performance degradation after the thermal stress test.

Referring back to the fabrication process, after forming the RRAM 510 as shown in FIGS. 10A and 10B, to protect the RRAM 510 from subsequent processes, a passivation layer (PASS) 512 may be deposited over the RRAM 510 as illustrated in FIG. 13. The PASS layer 512 may be deposited by either plasma-enhanced chemical vapor deposition (PECVD), or PVD. The PASS layer 512 may include but not limited to silicon nitride (SiN) and silicon dioxide (SiO₂).

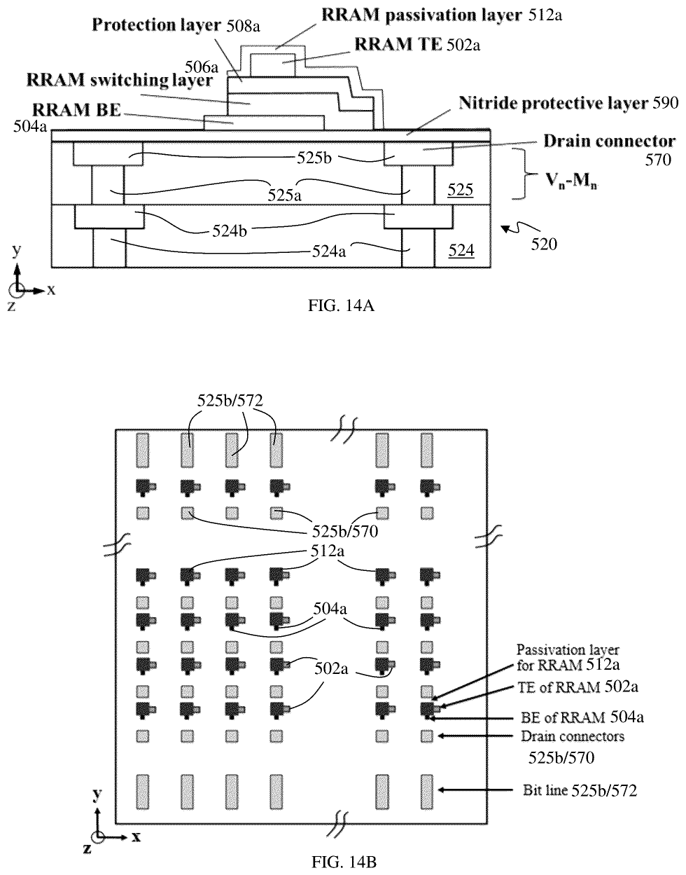

A patterning step may be designed and performed to ensure that the extended part of the the BE 504a and the TE 502a are not covered by the PASS layer 512a, as shown in FIGS. 14A and 14B in schematic cross-sectional and top views after patterning and etching of the PASS layer 512 to define the etched PASS layer 512a. The RRAM structure 510 may be protected by the PASS layer 512a while allowing the extended parts of the BE 504a and the TE 502a to remain open or exposed so that these extended parts can later be connected to the drain 570 and BL 572 connectors.

To connect the drain 570 and BL connectors 572 respectively to the RRAM BE 504a and TE 502a, openings are made in the silicon nitride layer 590 by lithography and etching steps to define via trenches 592 as shown in FIGS. 15A and 15B in schematic cross-sectional and top views. FIG. 15A shows the etching step to open via trench connection, while FIG. 15B shows the top view of the integrated circuit with RRAM after Mₙ via trench opening. The via trenches 592 allow access or electrical coupling to the drain connectors 570 and the through-vias 525a. The drain, source, gate, body and other pads, which are designed to wire bond, may also be opened in this process. Openings or trenches 593 may be formed or defined for the BL connectors 572. It is preferable to perform the etching step by ICP-RIE rather than ion-milling as ion milling may induce charges on the drain, source, gate etc. pads which may cause damage to transistors.

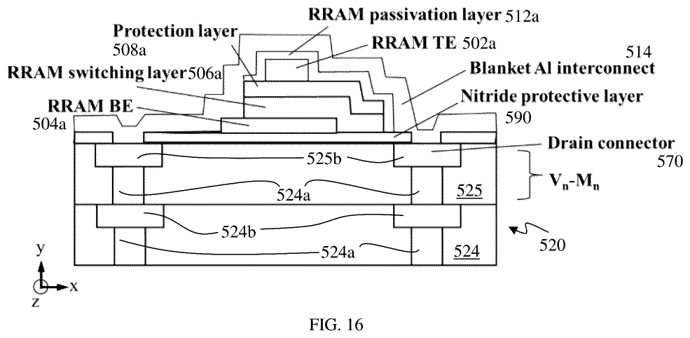

Subsequently, to fabricate the interconnect to enable electrical connection between RRAMs 510 and BL 572/drain 570 connectors, aluminium (Al) or copper (Cu) may be deposited on the structure by PVD. FIG. 16 shows a schematic cross-sectional view after deposition of an Al layer 514 for the fabrication of interconnects.

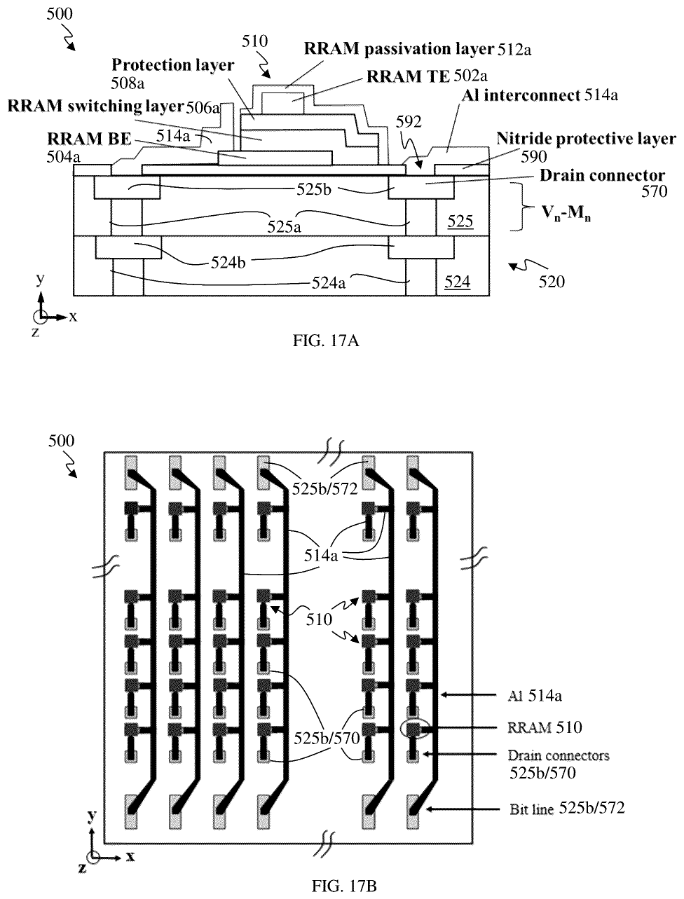

The Al layer 514 may undergo lithography and etching to define the desired interconnect configuration. FIGS. 17A and 17B show schematic cross-sectional and top views after lithography and etching of the Al layer 514 to defined Al interconnects 514a. The Al interconnects 514a connect the Mₙ drain pads 570 to the bottom electrodes 504a of the RRAMs 510 and the top electrodes 502a of the RRAMs 510 to the Mₙ bit lines 572. As shown in FIGS. 17A and 17B, a circuit arrangement or integrated circuit 500 may be obtained.

Further or final processing steps may include passivating the whole structure with nitride, and fabrication of subsequent via (Vₙ+1) and metal lines (Mₙ+1) if necessary.

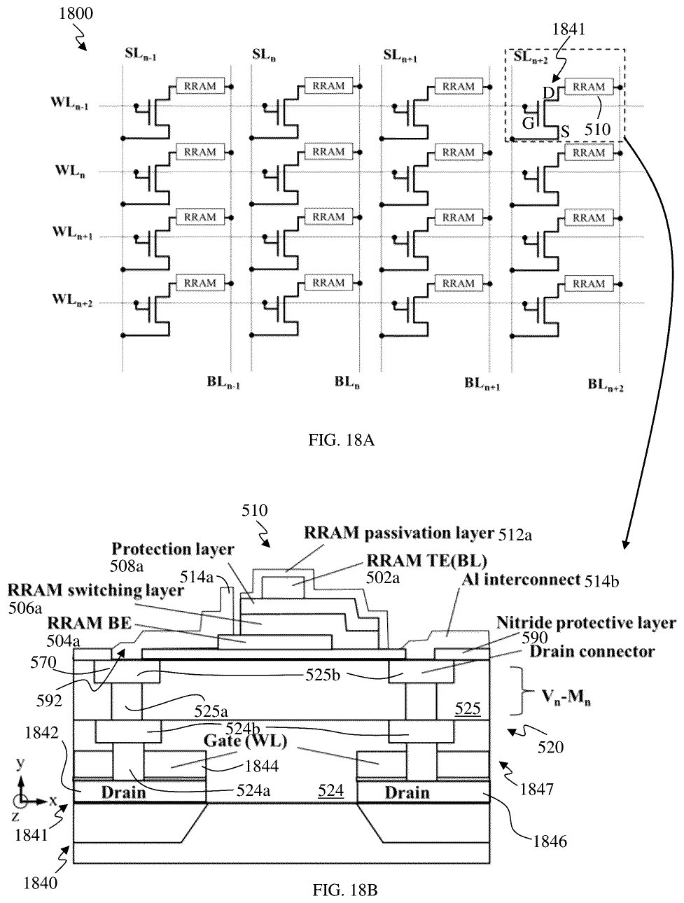

FIGS. 18A and 18B show schematic views of a circuit arrangement 1800 having a 1T1R configuration, according to various embodiments. As a non-limiting example, the circuit arrangement 1800 is based on the circuit arrangement 500 of FIGS. 17A and 17B. The circuit arrangement 1800 includes a plurality of two-terminal devices in the form of RRAMs, and is electrically coupled to a selection circuit 1840 having a plurality of selection devices in the form of transistors. Each transistor has a drain, a source, and a gate. The RRAMs and the transistors are electrically coupled in a one-to-one arrangement (i.e., 1T1R). Each pair of RRAM and the associated transistor is electrically coupled to a corresponding word line (WL), a corresponding source line (SL), and a corresponding a bit line (BL). Using the 1T1R arrangement shown inside the dashed square box of FIG. 18A as a non-limiting example, an RRAM 510 is electrically coupled to an associated transistor 1841. The gate (G) of the transistor 1841 is electrically coupled to a word line, WLₙ₋₁. The source(S) of the transistor 1841 is electrically coupled to a source line, SLₙ₊₂. The drain (D) of the transistor 1841 is electrically coupled to the bottom electrode (BE) of the RRAM 510. The top electrode (TE) of the RRAM 510 is electrically coupled to a bit line, BLₙ₊₂. A similar arrangement for each remaining pair of RRAM and the associated transistor, with electrical coupling to the corresponding WL, SL, and BL, may be provided, as shown in FIG. 18A.

FIG. 18B shows a schematic cross-sectional view of the RRAM 510 and the transistor 1841 illustrated inside the dashed square box of FIG. 18A. The structure of the RRAM 510 may be as previously described in the context of the fabrication process of FIGS. 5 to 17B. The transistor 1841 includes a drain 1842 that may be electrically coupled, via the through-vias 524a, 525a, the metallisation layer 524b, the drain connector 570 of the metallisation layer 525b of the via interconnection circuit 520, and the Al interconnect 514a, to the bottom electrode (BE) 504a of the RRAM 510. The top electrode (TE) 502a of the RRAM 510 may be electrically coupled to a corresponding bit line (BL). The transistor 1841 further includes a gate 1844 that may be electrically coupled to a corresponding word line (WL). The transistor 1841 further includes a source (not shown) that may be electrically coupled to a corresponding source line (SL). Also shown in FIG. 18B is a partial view of an Al interconnect 514b for electrical coupling of the BE of another RRAM (not shown), by means of the via interconnection circuit 520, to the drain 1846 of another transistor 1847.

An off-via fabrication technique for RRAM devices has been described in exemplary and detailed manner. It should be understood that various changes can be made to the function and arrangement of different elements without deviating from the scope of the invention as defined by the appended claims.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A circuit arrangement comprising:
a plurality of two-terminal devices;
a via interconnection circuit comprising:
a support structure;
a plurality of through-vias defined through the support structure; and
a plurality of via trenches defined in the support structure, the plurality of via trenches being arranged to allow electrical coupling to the plurality of through-vias; and
a selection circuit comprising a plurality of selection devices,
wherein, for each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias.

2. The circuit arrangement as claimed in claim 1, wherein the via interconnection circuit further comprises:
at least one metal line electrically coupled to the plurality of through-vias, wherein the plurality of via trenches are arranged to allow electrical coupling to the at least one metal line,
wherein the two-terminal device is electrically coupled to the respective selection device through the respective via trench, the respective through-via and the at least one metal line.

3. The circuit arrangement as claimed in claim 1, wherein the two-terminal device comprises a memory device.

4. The circuit arrangement as claimed in claim 3, wherein the memory device comprises:
a first electrode;
a second electrode; and
a resistive switching material in between the first electrode and the second electrode.

5. The circuit arrangement as claimed in claim 4, wherein the memory device further comprises a protective layer in between the resistive switching material and one of the first and second electrodes.

6. The circuit arrangement as claimed in claim 1, wherein each selection device of the plurality of selection devices comprises a transistor.

7. The circuit arrangement as claimed in claim 1, wherein the support structure comprises a shielding layer, wherein the plurality of via trenches are defined through the shielding layer.

8. A method of forming a circuit arrangement comprising:
forming a plurality of two-terminal devices on a via interconnection circuit of the circuit arrangement, the via interconnection circuit comprising:
a support structure;
a plurality of through-vias defined through the support structure; and
a plurality of via trenches defined in the support structure, the plurality of via trenches being arranged to allow electrical coupling to the plurality of through-vias; and
electrically coupling the plurality of two-terminal devices to a selection circuit of the circuit arrangement, the selection circuit comprising a plurality of selection devices,
wherein, for each two-terminal device of the plurality of two-terminal devices, the two-terminal device is arranged outside of a respective via trench of the plurality of via trenches, the two-terminal device being electrically coupled to a respective selection device of the plurality of selection devices in a one-to-one arrangement through the respective via trench and a respective through-via of the plurality of through-vias.

9. The method as claimed in claim 8, wherein the via interconnection circuit further comprises:
at least one metal line electrically coupled to the plurality of through-vias, wherein the plurality of via trenches are arranged to allow electrical coupling to the at least one metal line,
wherein the two-terminal device is electrically coupled to the respective selection device through the respective via trench, the respective through-via and the at least one metal line.

10. The method as claimed in claim 8 or 9, wherein the two-terminal device comprises a memory device.

11. The method as claimed in claim 10, wherein the memory device comprises:
a first electrode;
a second electrode; and
a resistive switching material in between the first electrode and the second electrode.

12. The method as claimed in claim 11, wherein the memory device further comprises a protective layer in between the resistive switching material and one of the first and second electrodes.

13. The method as claimed in claim 8, wherein each selection device of the plurality of selection devices comprises a transistor.

14. The method as claimed in claim 8, wherein the support structure comprises a shielding layer, wherein the plurality of via trenches are defined through the shielding layer.
